(19) United States
(12) Patent Application Publication
(10) Pub. No.: US 2026/0186428 A1
(43) Pub. Date: Jul. 2, 2026

(54) MEASUREMENT ARRANGEMENT FOR DETERMINING THE POSITION OF A MOVABLE COMPONENT

(71) Applicant: Carl Zeiss SMT GmbH, Oberkochen (DE)

(72) Inventor: Holger MUENZ, Aalen (DE)

(21) Appl. No.: 19/548,616

(22) Filed: Feb. 24, 2026

Related U.S. Application Data
(63) Continuation of application No. PCT/EP2024/074306, filed on Aug. 30, 2024.

(30) Foreign Application Priority Data
Sep. 4, 2023 (DE) 10 2023 208 513.5

(51) Int. Cl. G03F 7/00; G01B 11/00; G01N 21/95

(52) U.S. Cl. CPC G03F 7/7085; G03F 7/70258; G01B 11/005; G01N 21/9501

(57) ABSTRACT

A measurement arrangement for determining the position of a movable component in a microlithographic optical system comprises: an optical resonator having two resonator mirrors which enclose a resonator cavity; and a movable measurement mirror which is assigned to the component and arranged within the resonator cavity for the purpose of directing measurement radiation back and forth between the resonator mirrors. The measurement mirror is arranged at a working distance from one of the resonator mirrors which has a curvature matched to the measurement mirror in such a way that the centre of the curvature is arranged on, or at a distance of no more than 20% of the working distance from, the measurement mirror.

### CROSS-REFERENCE TO RELATED APPLICATIONS

The present application is a continuation of, and claims benefit under 35 USC 120 to, international application No. PCT/EP2024/074306, filed Aug. 30, 2024, which claims benefit under 35 USC 119 of German Application No. 10 2023 208 513.5, filed Sep. 4, 2023. The entire disclosure of each of these applications is incorporated by reference herein.

### FIELD

The disclosure relates to a measurement arrangement for determining the position of a movable component in a microlithographic optical system, a microlithographic projection exposure apparatus, an illumination device, a projection lens, an inspection apparatus and a coordinate measuring apparatus, each having at least one such measurement arrangement.

### BACKGROUND

Microlithography is used for producing microstructured components, such as for example integrated circuits or LCDs. This is implemented using a so-called projection exposure apparatus, which comprises an illumination device and a projection lens. In this context, the image of a mask situated on a reticle and illuminated via the illumination device is projected via the projection lens onto a substrate (e.g. a silicon wafer) coated with a light-sensitive layer (photoresist) and arranged in the image plane of the projection lens, in order to transfer the mask structure to the light-sensitive coating of the substrate.

During operation of such projection lenses, during which mask and wafer are usually moved relative to one another in a scanning process, the positions of the mirrors, which are movable in part in all six degrees of freedom, are set and maintained with relatively accuracy both with respect to one another and also with respect to mask and/or wafer in order to avoid or at least reduce aberrations and accompanying impairments of the imaging result. This determination of position may involve relatively high accuracies, especially in EUV lithography.

Diverse approaches for measuring the position of the individual lens mirrors and also of the wafer or the wafer stage and the reticle plane are known. Besides interferometric measurement apparatuses, frequency-based position measurement using an optical resonator is also known here.

A structure used to this end according to FIG. 3 in U.S. Pat. No. 11,274,914B2 comprises a resonator having two resonator mirrors, a retroreflector in the form of a triple mirror, and a plane mirror that serves as a measurement target and on which the beam path is folded. The resonator mirrors and the triple mirror represent a measuring head which is securely connected to the housing of the projection lens in the projection exposure apparatus, and the measurement target is fastened to an element, intended to be measured in terms of its position, of the projection exposure apparatus. The actual distance measurement equipment comprises a radiation source, which is tunable with respect to its optical frequency and which creates input coupling radiation that passes through a beam splitter and is input coupled into the optical resonator. In that case, the radiation source is controlled by a coupling device in such a way that the optical frequency of the radiation source is tuned to the resonant frequency of the optical resonator and is thus coupled to the resonant frequency. Input coupling radiation output coupled via a beam splitter is analysed using an optical frequency measuring device which can comprise e.g. a frequency comb generator for highly accurate determination of the absolute frequency. If the position of the component to be measured changes in the direction of extent of the resonator, then together with the distance between the resonator mirrors the resonant frequency of the optical resonator also changes and hence—owing to the coupling of the frequency of the tunable radiation source to the resonant frequency of the resonator—the optical frequency of the input coupling radiation changes as well, which is in turn registered directly by the frequency measuring device.

The use of a plane mirror as measurement target, depicted in FIG. 3 of U.S. Pat. No. 11,274,914B2, is possible rather than a triple mirror, which could also be used here, for optomechanical reasons, for example with regards to the avoidance of a multiplicity of reflections and the reduction in the size of the structure. However, a slight tilt of the plane mirror during the axial displacement thereof implemented during the measurement mode may lead to a lateral offset of the mode formed in the resonator on the resonator mirror serving as input coupling mirror, whereby the coupling efficiency of the radiation field (=“input coupling field”) present at the input of the resonator path into the mode field of the optical resonator (=“resonator field”) is reduced. A reduction in the coupling efficiency beyond a certain tolerance limit is to the detriment of the measurement accuracy of the position measurement, with the result that the measurement may become unusable. Similar effects may also occur when non-planar mirrors are used as measurement target.

### SUMMARY

The disclosure seeks to provide an improved measurement apparatus which can have, for example, a relatively compact structure and a relatively high measurement accuracy can be obtained when determining the position.

According to an aspect, the disclosure provides a measurement arrangement for determining the position of a movable component in a microlithographic optical system. The measurement arrangement comprises an optical resonator having two resonator mirrors which enclose a resonator cavity, and a movable measurement mirror which is assigned to the component and arranged within the resonator cavity for the purpose of directing measurement radiation back and forth between the resonator mirrors. In this case, the measurement mirror is arranged at a working distance from one of the resonator mirrors which has a curvature matched to the measurement mirror in such a way that the centre of the curvature, i.e. the centre of curvature of the aforementioned resonator mirror, is arranged on, or at a distance of no more than 20%, for example no more than 10%, for example no more than 5%, or for example no more than 1%, of the working distance from, the measurement mirror.

The phrasing whereby the centre of the curvature is located on the measurement mirror should be understood as meaning that the centre is arranged on a reflective surface that serves to direct the measurement radiation back and forth. In other words, the measurement mirror is arranged at a distance of no more than 10% of the working distance from the centre of curvature of the first resonator mirror. The measurement mirror can serve to fold the beam path of the measurement radiation in the optical resonator. The working distance between the resonator mirror with the matched curvature and the measurement mirror should be understood to mean the length of the beam path of the measurement radiation between the resonator mirror and the measurement mirror for the case in which the measurement mirror is tilted in relation to the aforementioned resonator mirror. In this context, the length of the beam path is measured along the axis of the beam path.

The matching of the curvature of one of the resonator mirrors to the measurement mirror in such a way that the centre thereof is arranged on, or at a distance of no more than 20%, for example no more than 10%, no more than 5% or no more than 1%, of the working distance from, the measurement mirror ensures that a tilt of the measurement mirror brings about no lateral displacement or only a small lateral displacement on the other resonator mirror, by which the measurement radiation is input coupled into the resonator cavity. Hence, the coupling efficiency of the input coupling field into the mode field of the resonator can be maintained at a relatively high level using the arrangement according to the disclosure, and hence a relatively high measurement accuracy can be obtained.

Should the centre of the first-mentioned resonator mirror be arranged on the measurement mirror, the beam position on the other resonator mirror can be perfectly stable when tilting the measurement mirror. The reason for this is that the position of the centre of curvature of the first-mentioned resonator mirror, as seen from the other resonator mirror via the measurement mirror, can remain unchanged even when the measurement mirror is tilted. Should the centre of curvature of the first-mentioned resonator mirror deviate from the position on the measurement mirror by no more than 20%, for example no more than 10%, no more than 5% or no more than 1%, of the working distance, i.e. only slightly, there is only a relatively small lateral displacement of the resonator mode on the other resonator mirror, the influence of which on the coupling efficiency, and hence on the measurement accuracy, may be tolerable.

According to an embodiment, one of the resonator mirrors is configured as an input coupling mirror for input coupling measurement radiation into the resonator cavity and the other resonator mirror is configured as a counter mirror to the input coupling mirror, the resonator mirror with the curvature matched to the measurement mirror being the counter mirror.

According to an embodiment, the optical resonator is configured to form a beam path with a beam waist for the measurement radiation, the beam waist being located between the measurement mirror and the first resonator mirror with the curvature matched to the measurement mirror. A beam waist should be understood to mean the location of the beam path in the optical resonator at which the beam has the smallest diameter or radius. According to an embodiment, the beam path within the resonator cavity is embodied as a Gaussian beam.

According to an embodiment, the beam waist is arranged at a distance of at least 5% of the working distance from the measurement mirror and at a distance of at least 5% of the working distance from the first resonator mirror. According to an embodiment, the beam waist is arranged at a distance of at least 10%, at least 20% or at least 40%, of the working distance from the measurement mirror and at a distance of at least 10%, at least 20% or at least 40%, from the first resonator mirror. According to an embodiment, the beam waist is located centrally between the measurement mirror and the first resonator mirror.

According to an embodiment, the further resonator mirror of the optical resonator that encloses the resonator cavity together with the resonator mirror with the curvature matched to the measurement mirror has a curvature whose centre is located on the side of the measurement mirror opposite the further resonator mirror and is at a distance of at least 10% of the working distance from the measurement mirror. The centre is arranged at a distance from the measurement mirror of at least 10%, for example at least 50%, of the distance between the further resonator mirror and the measurement mirror. According to an embodiment variant, the radius of curvature of the further resonator mirror is matched to the length of the resonator cavity and the radius of curvature of the first resonator mirror such that a Gaussian mode forms in the optical resonator.

According to an embodiment, the further resonator mirror enclosing the resonator cavity together with the first resonator mirror has a curvature, with the relationship set forth below applying to the radius of curvature R2 of the first resonator mirror, the radius of curvature R1 of the further resonator mirror and a relative distance a of the beam waist from the first resonator mirror in relation to the working distance:

$$R 1 = R 2 ( 3 + \frac{2}{- 2 + a} ) ,$$

or there being a deviation from this relationship of no more than 10%.

According to an embodiment, the measurement mirror is configured as a plane mirror.

According to an embodiment, the optical resonator is configured such that the measurement radiation radiated at the measurement mirror makes an angle of no more than 100 mrad, for example of no more than 20 mrad, with the measurement radiation reflected thereon.

According to an embodiment, the two resonator mirrors are arranged offset from one another in relation to the direction of incidence of the measurement radiation at the measurement mirror. In other words, the two resonator mirrors are arranged axially offset from one another. In this case, the two resonator mirrors are arranged in a manner substantially aligned to one another, i.e. the respective directions of incidence of the measurement radiation on the resonator mirrors deviate from one another by less than 100 mrad, for example by less than 20 mrad.

According to an embodiment variant, the two resonator mirrors are arranged offset by at least one thickness of one of the resonator mirrors. As a result, edge regions of one of the resonator mirrors provided for the beam path of the measurement radiation cannot be arranged so as to overlap the other resonator mirror and hence a tilt angle of the measurement mirror cannot be reduced vis-à-vis the measurement radiation radiated thereon.

According to an embodiment, the optical resonator is configured such that the measurement radiation radiated at the measurement mirror makes an angle of no more than 1 mrad with the measurement radiation reflected thereon.

According to an embodiment, a polarization beam splitter is arranged in the beam path of the optical resonator, and the beam path of the measurement radiation between the measurement mirror and one of the resonator mirrors is deflected thereon. The deflection is through approximately 90°. To this end, a quarter wave plate, for example, can be arranged in the beam path between the measurement mirror and the specified resonator mirror. Hence, the measurement mirror can be arranged for direct retroreflection of the incident measurement radiation, i.e. the directions of the incoming and reflected measurement radiations are collinear.

According to an embodiment, the resonator is operated in a Laguerre-Gauss mode with an azimuthal index of at least one. Thus, the azimuthal index can be for example three; in this case, the radial index can be zero. According to an embodiment variant, the measurement arrangement comprises a diffractive optical element in the form of a CGH (computer-generated hologram) for such beam shaping of the measurement radiation input coupled into the optical resonator that there can be pure-mode coupling of the resonator cavity to the Laguerre-Gauss mode. Hence, the measurement mirror can be arranged for direct retroreflection of the incident measurement radiation, i.e. the directions of the incoming and reflected measurement radiations are collinear.

According to an embodiment, one of the two resonator mirrors has a central cutout in which the other resonator mirror is arranged. Hence, the measurement mirror can be arranged for direct retroreflection of the incident measurement radiation, i.e. the directions of the incoming and the reflected measurement radiations are collinear.

According to an embodiment, the working distance is at least 2 cm, for example at least 10 cm, at least 20 cm, or at least 50 cm.

Furthermore, a microlithographic projection exposure apparatus is provided according to the disclosure. The projection exposure apparatus comprises at least one movable component and at least one measurement arrangement in one of the above-described embodiments or embodiment variants for determining the position of the movable component. According to an embodiment variant, the projection exposure apparatus is configured for operation in the EUV wavelength range. Alternatively, the measurement arrangement in one of the above-described embodiments or embodiment variants can also be integrated in a mask inspection apparatus or a wafer inspection apparatus.

According to an embodiment, the projection exposure apparatus comprises a plurality of optical elements for guiding exposure radiation in the projection exposure apparatus, with one of the optical elements serving as the movable component. This optical element can be part of a projection lens or an illumination device of the projection exposure apparatus. As a person skilled in the art is aware, such an illumination device serves to illuminate the mask during an exposure process, and the projection lens serves to image mask structures onto a wafer.

Furthermore, in an embodiment, an illumination device for a microlithographic projection exposure apparatus is provided according to the disclosure, the illumination device having at least one movable component and at least one measurement arrangement in one of the above-described embodiments or embodiment variants for determining the position of the movable component. The movable component may be a lens or a mirror of the illumination device. The illumination device can also be referred to as illumination system or illumination optics.

Furthermore, in an embodiment, a projection lens for a microlithographic projection exposure apparatus is provided according to the disclosure, the projection lens having at least one movable component and at least one measurement arrangement in one of the above-described embodiments or embodiment variants for determining the position of the movable component. The movable component may be a lens or a mirror of the projection lens.

Furthermore, in an embodiment, an inspection apparatus for inspecting a surface of a substrate is provided according to the disclosure, the inspection apparatus having at least one movable component and at least one measurement arrangement in one of the above-described embodiments or embodiment variants for determining the position of the movable component. The substrate may be a mask or a wafer for microlithography.

In an embodiment, the movable component can be a component in an optical system of the inspection apparatus. An example of such an inspection apparatus for mask or wafer inspection (without the measuring arrangement according to the disclosure) is known from the publication DE 102012205181A1, the entire content of which is incorporated by reference into the present specification.

Furthermore, in an embodiment, a coordinate measuring apparatus is provided according to the disclosure, the coordinate measuring apparatus having at least one movable component and at least one measurement arrangement in one of the above-described embodiments or embodiment variants for determining the position of the movable component.

In an embodiment, the movable component can be a component in an optical system of the coordinate measuring apparatus, which can also be referred to as coordinate measuring machine. The coordinate measuring apparatus is used to determine a respective positional deviation of one or more measuring points on a test component from a respective nominal position. An example of such a coordinate measuring apparatus (without the measuring arrangement according to the disclosure) is known from the publication DE10 2019 213 794A1, the entire content of which is incorporated by reference into the present specification.

Certain specifics in relation to the above-mentioned embodiments, exemplary embodiments and embodiment variants, etc., of the measurement arrangement according to the disclosure are explained in the description of the figures and the claims. The individual features can be implemented, either separately or in combination, as embodiments of the disclosure. Furthermore, they can describe embodiments which are independently protectable and protection for which is claimed only during or after pendency of the application, as the case may be.

### BRIEF DESCRIPTION OF THE DRAWINGS

The aforementioned features and further features of the disclosure will be illustrated in the following detailed description of exemplary embodiments according to the disclosure or of embodiments or embodiment variants with reference to the attached schematic drawings, in which:

FIG. 1 shows an embodiment according to the disclosure of a measurement arrangement, which is configured to determine the position of a movable component and which comprises a resonator cavity and a measurement mirror arranged therein;

FIG. 2A shows the beam path in the resonator cavity of the measurement arrangement according to the disclosure according to FIG. 1 in a simplified illustration;

FIG. 2B shows the beam path of a resonator cavity of a comparison example of the measurement arrangement;

FIG. 3 shows a beam generation and evaluation device of the measurement arrangement according to FIG. 1;

FIG. 4 shows a Rayleigh length z_{R} in the resonator cavity of the measurement arrangement according to FIG. 1, as a function of a relative distance a of a beam waist in the resonator cavity in relation to a working distance of a measurement mirror;

FIG. 5 shows the radius of curvature R1 of a resonator mirror delimiting the resonator cavity, as a function of the relative distance a;

FIG. 6 shows the dependence of different beam radii in the resonator cavity on the relative distance a;

FIG. 7 shows an embodiment according to the disclosure of the measurement arrangement for determining the position of a movable component;

FIG. 8 shows an embodiment according to the disclosure of the measurement arrangement for determining the position of a movable component;

FIG. 9 shows an embodiment according to the disclosure of the measurement arrangement for determining the position of a movable component;

FIG. 10 shows a portion of a microlithographic projection exposure apparatus having a movable component, the position of which is determinable with a measurement arrangement according to any of FIGS. 1, 7, 8 and 9;

FIG. 11 shows an embodiment of the projection exposure apparatus according to FIG. 10; and

FIG. 12 shows an enlarged detailed view of the projection exposure apparatus according to FIG. 11 with a measurement arrangement according to any of FIGS. 1, 7, 8 and 9 integrated therein.

### DETAILED DESCRIPTION

In the exemplary embodiments or embodiments or embodiment variants described below, elements which are functionally or structurally similar to one another are provided with the same or similar reference signs as far as possible. Therefore, for understanding the features of the individual elements of a specific exemplary embodiment, reference should be made to the description of other exemplary embodiments or the general description of the disclosure.

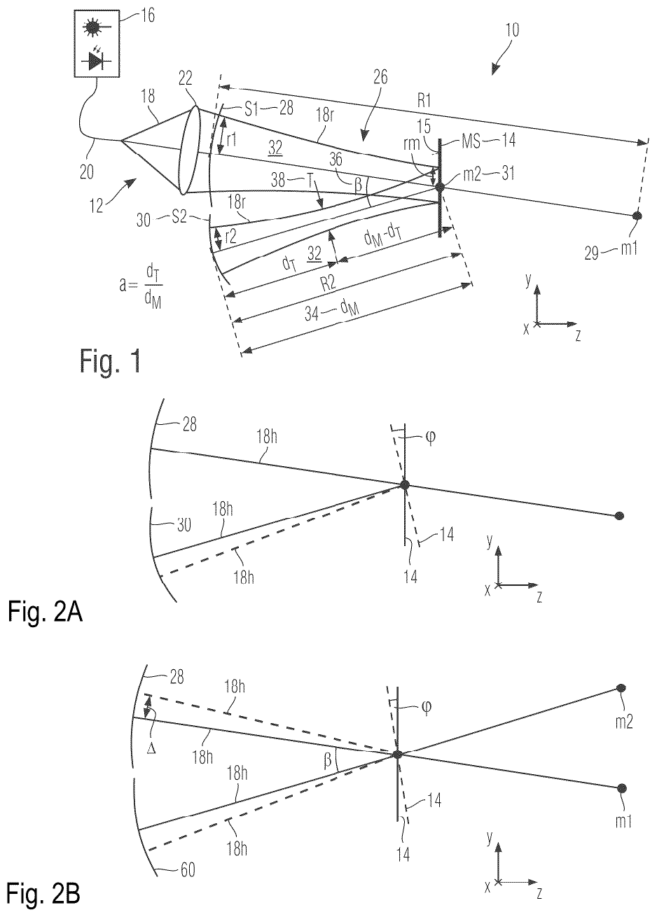

In order to facilitate the description, a Cartesian xyz-coordinate system is indicated in the drawing, from which system the respective positional relationship of the components illustrated in the figures is evident. In FIG. 1, the x-direction runs perpendicular and into the plane of the drawing, the z-direction toward the right, and the y-direction upwardly.

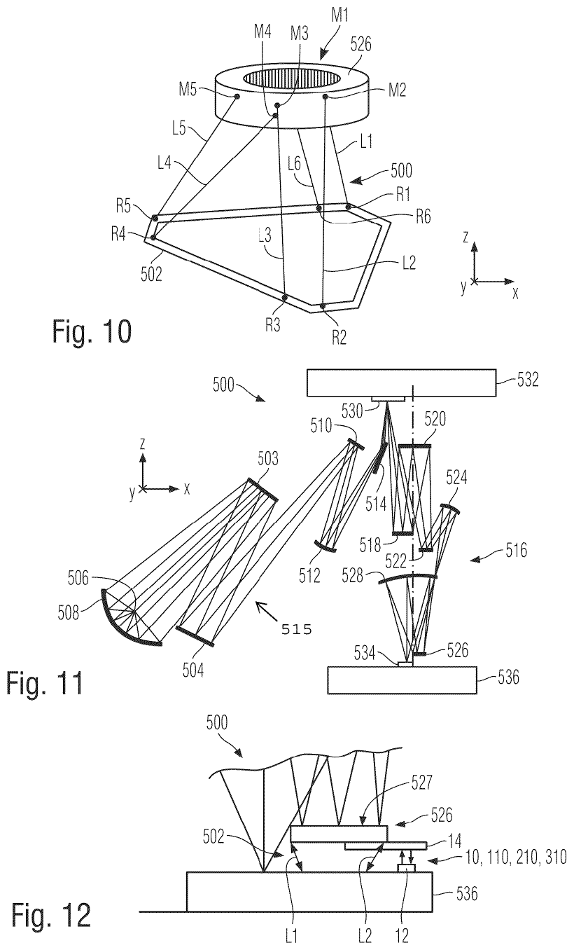

FIG. 1 illustrates an embodiment 10 of a measurement apparatus according to the disclosure. This measurement apparatus 10 is configured to determine the position of a movable component of a microlithographic optical system 500, which is illustrated in sections in FIG. 10 in an exemplary embodiment. The measurement arrangement 10 according to FIG. 1 comprises a measuring head 12 and a measurement mirror MS (reference sign 14), which can also be referred to as measurement target and which is fastened, and hence assigned, to the movable component. To determine the position of the movable component, the measurement arrangement 10 is used to determine the distance between the measuring head 12 and the measurement mirror 14, as described in detail further below.

FIG. 11 shows a simplified illustration of the optical system 500 in the form of a microlithographic projection exposure apparatus. FIG. 10 shows a section of the projection exposure apparatus according to FIG. 11 with a mirror 526, which in this case serves as the aforementioned movable component. In the illustrated embodiment, the movable component in form of the mirror 526 is a component of a projection lens 516 of the projection exposure system. Alternatively, the movable component can also be a component of an illumination device 515 of the projection exposure system.

As mentioned, the component in the present exemplary embodiment is the mirror 526 which is movably mounted on a support structure 502 depicted in FIG. 10 or on a housing of the optical system 500. The support structure 502 or the housing is also referred to as reference frame below. To monitor the position and/or the orientation of the component 526 in relation to the reference frame during ongoing operation, i.e. in situ, the distance of selected measurement points M from the support structure 502 is ascertained.

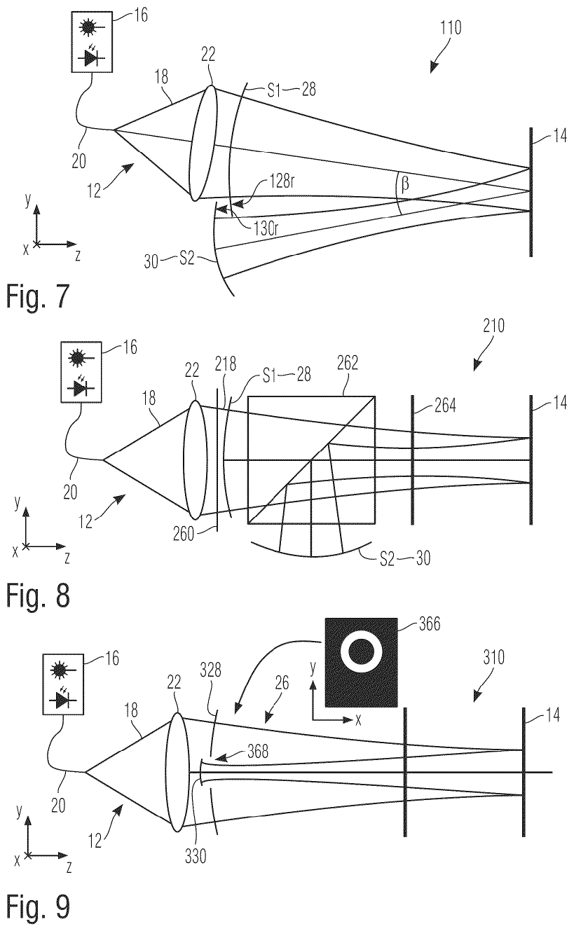

According to the present exemplary embodiment, the position of six measurement points M1 to M6, for example in a hexapod configuration as depicted by way of example in FIG. 10, is respectively determined in relation to an associated reference point R1 to R6 on the support structure 502. Thus, six hexapod lengths L1 to L6 are ascertained. The ascertainment of the respective position of the six measurement points M1 to M6 is implemented by measuring the lengths L1 to L6, in each case with an embodiment of the aforementioned measurement arrangement 10 or an embodiment of the measurement arrangements 110, 210 and 310 described below with reference to FIGS. 7 to 9, respectively.

The microlithographic projection exposure apparatus depicted in FIG. 11 and serving as optical system 500 is designed for operation with EUV exposure radiation. In this text, EUV radiation should be understood to mean electromagnetic radiation at a wavelength of less than 100 nm, for example a wavelength of approximately 13.5 nm or approximately 6.8 nm. However, the present disclosure is not limited to the application in such an apparatus but is also realizable when measuring projection exposure apparatuses with different operating wavelengths, for example operating wavelengths in the VUV or DUV range. In further applications, the disclosure can also be realized in a different microlithographic optical system, for instance a mask inspection apparatus or a wafer inspection apparatus, or a coordinate measuring apparatus.

According to the exemplary embodiment in FIG. 11, the optical system 500 in the form of an EUV projection exposure apparatus comprises a field facet mirror 503 and a pupil facet mirror 504. The light from a light source unit comprising a plasma light source 506 and a collector mirror 508 is directed to the field facet mirror 503. A first telescope mirror 510 and a second telescope mirror 512 are arranged downstream of the pupil facet mirror 504 in the light path. Arranged downstream in the light path is a deflection mirror 514, which directs the radiation incident thereon to an object field in the object plane of a projection lens 516 comprising six mirrors 518, 520, 522, 524, 526 and 528. The collector mirror 508, the field facet mirror 503, the pupil facet mirror 504, the two telescope mirrors 510 and 512 and the deflection mirror 514 together form the illumination device 515 of the projection exposure apparatus. The radiation from the plasma light source 506 passes through the illumination device 515 and then strikes the object field in the object plane, i.e. the illumination device 515 illuminates the object field.

A reflective structure-bearing mask 530 on a mask stage 532 is arranged at the location of the object carrier, the mask being imaged by way of the projection lens 516 into an image plane, in which a substrate 534 coated with a light-sensitive layer (photoresist) is located on a wafer stage 536.

FIG. 12 shows an enlarged detailed view of the projection exposure apparatus from FIG. 11, which serves as optical system 500, in the region of the mirror 526, which serves as movable component, in the projection lens 516. In this case, FIG. 12 shows in simplified fashion the measurement arrangement 10 or the measurement arrangements 110, 210 and 310 respectively shown in FIGS. 7, 8 and 9 by way of example. For example, the mirror 526 is movably held on the housing or on the wafer stage 536 by the support structure 502 in this case and thus represents the movable component in this exemplary embodiment. For reasons of clarity, the support structure 502 has not been shown in detail in the present case. The measuring head 12 of the measurement arrangement 10, 110, 210 or 310 is arranged stationarily on the housing or, for example, on the mask stage. The measurement mirror 14 is fastened to the underside of the mirror 526 opposite the side 527 of the mirror 526 which reflects the exposure radiation of the projection exposure apparatus 500. According to one exemplary embodiment, the mirror 526 is adjusted in its position depending on the result of the position measurement by the measurement arrangement 10 or 110, 210 or 310 and further measurement arrangements 10, 110, 210 or 310 provided for example in accordance with the configuration illustrated in FIG. 10.

The measurement arrangement 10 illustrated in FIG. 1 comprises a radiation generation and evaluation device 16 for generating and evaluating measurement radiation 18, optionally an optical fibre 20, a beam shaping optical unit in the form of an input coupling lens element 22, two resonator mirrors S1 (reference sign 28) and S2 (reference sign 30) and the measurement mirror 14 already mentioned above. The two resonator mirrors 28 and 30 can be integrated in a resonator module, whereby they are secured relative to one another. Together with the measurement mirror 14, the resonator mirrors 28 and 30 form an optical resonator 26. The measuring head 12 likewise already mentioned above comprises at least the two resonator mirrors 28 and 30 and the input coupling lens element 22. The beam generation and evaluation device 16 can likewise be part of the measuring head 12 or else be arranged outside of the latter, as illustrated in FIG. 1.

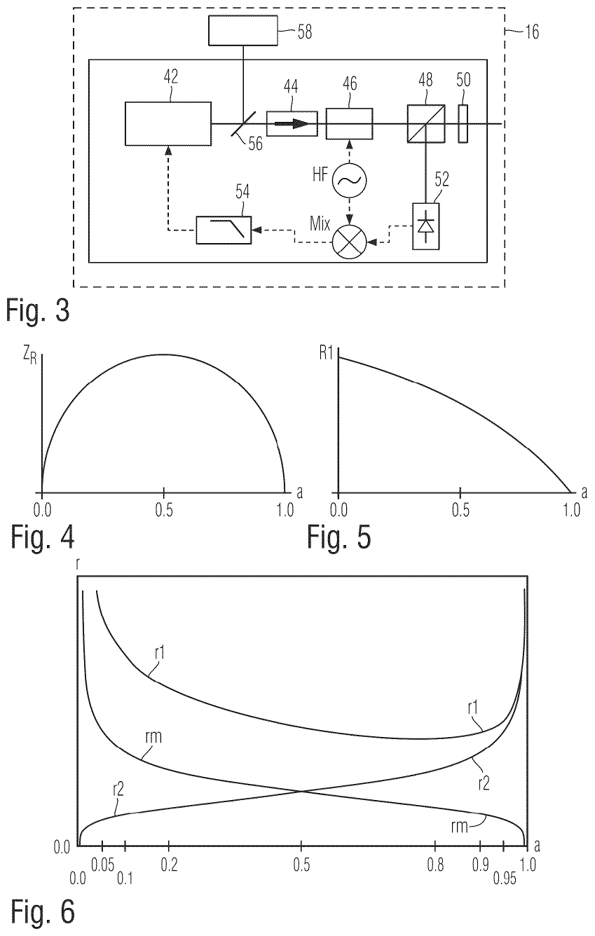

An exemplary embodiment of the beam generation and evaluation device 16 is depicted in detail in FIG. 3. It is based on the principle whereby a laser 42 that is tunable with regards to the optical frequency follows a frequency of the optical resonator 26 using a suitable control loop (according to the Pound-Drever-Hall method in the example illustrated), such that the length L of the resonator 26 that is ultimately to be measured is encoded as a frequency of the tunable laser 42. The laser 42 serves as radiation source for the measurement radiation 18, which for example is located in the visible or infrared wavelength range.

The beam generation and evaluation device 16 comprises a Faraday isolator 44, an electro-optic modulator 46, a polarization-optical beam splitter 48, a quarter wave plate 50, a photodetector 52 and a low-pass filter 54. The portion of the measurement radiation 18 that passes through the quarter wave plate 50 enters the measuring head 12 via the optical fibre 20 depicted in FIG. 1. Referring back to FIG. 3, for the purpose of frequency measurement, a portion of the measurement radiation 18 emitted by the tunable laser 42 is output coupled via a beam splitter 56 and fed to an analyser 58 for frequency measurement. The actual frequency measurement in the analyser 58 can be effected for example by way of the comparison with a frequency reference, e.g. an fs frequency comb of a femtosecond laser. The measurement radiation 18 according to FIG. 1 leaving the optical resonator 16 again via the measuring head 12 re-enters the beam generation and evaluation device 16 via the optical fibre 20 and is captured by the photodetector 52. Regarding further details as regards to the functionality of the beam generation and evaluation device 16, reference is made to DE 10 2018 208 147 A1.

As already mentioned above, the optical resonator 26 is formed by the resonator mirrors 28 and 30 in conjunction with the measurement mirror 14 serving as measurement target. In this case, the resonator mirrors 28 and 30 enclose a resonator cavity 32. The resonator mirror 28 serves as input coupling mirror for input coupling the measurement radiation 18 into the resonator cavity 32. The resonator mirror 30 serves as counter mirror to the resonator mirror 28.

In the embodiment shown, the resonator mirror 28 serving as input coupling mirror has a curved mirror surface, with the radius of curvature R1 being greater than the distance between the resonator mirror 28 and the measurement mirror 14. Hence, the centre of curvature m1 (reference sign 29) of the resonator mirror 28 is located on the side of the measurement mirror 14 opposite to the resonator mirror 28 and hence outside of the resonator cavity 32.

The resonator mirror 30 serving as counter mirror likewise has a curved mirror surface, with a centre m2 (reference sign 31) of its curvature being arranged on the measurement mirror 14, i.e. on a reflective surface 15 of the measurement mirror. Alternatively, the centre m2 may be at a certain distance from the measurement mirror 14, the distance being no more than 10% of a working distance d_{M} (reference sign 34) of the resonator mirror 30 from the measurement mirror 14.

The measurement mirror 14 is arranged to direct the measurement radiation 18 back and forth between the two resonator mirrors 28 and 30, which are both arranged substantially in the positive z-direction and hence arranged in a manner substantially aligned to one another. In the exemplary embodiment according to FIG. 1, the resonator mirrors 28 and 30 and the measurement mirror 14 are arranged in such a way that the measurement radiation 18 radiated onto the measurement mirror 14 makes a folding angle β (reference sign 36) of for example less than 100 mrad, for example less than 20 mrad, with the measurement radiation 18 reflected thereon. Hence the orientation of the resonator mirrors 28 and 30 deviates from the exactly aligned orientation only by the angle β. In other words, the respective directions of incidence of the measurement radiation 18 at the resonator mirrors 28 and 30 deviate from one another by the angle β. In other words, the measurement mirror 14 has the function of a folding mirror for folding the beam path of the measurement radiation 18 within the resonator cavity 32.

The effects on the measurement accuracy of the measurement arrangement 10 of the configuration of this kind of the resonator mirror 30 in which the centre of curvature M2 thereof is located on, or at a distance of no more than 10% of the working distance d_{M} from, the measurement mirror 14 are explained below with reference to FIGS. 2A and 2B. FIG. 2A schematically depicts the beam path of the measurement radiation 18 in the resonator 26 of the measurement arrangement 10 by way of the central chief ray 18h. FIG. 2B illustrates the beam path of a comparison example of the measurement arrangement, in which the resonator mirror 60 (counter mirror) corresponding to the resonator mirror 30 is configured with the same curvature as the resonator mirror 28 acting as the input coupling mirror. That is to say, the centre of curvature m2 of the resonator mirror 60 is arranged at a distance of far more than 10% of the working distance d_{M} from the measurement mirror 14. Should the measurement mirror 14 now be tilted through a tilt angle q, the chief ray 18h tilts in the region between the measurement mirror 14 and the resonator mirror 30 and, respectively, 60 serving as counter mirror, both in the arrangement according to FIG. 2A and according to FIG. 2B, as depicted by the dashed line.

In the comparison example according to FIG. 2B, the chief ray 18h also tilts in the region between the resonator mirror 28 and the measurement mirror 14, i.e. there is a lateral displacement of the beam path of the measurement radiation 18 on the resonator mirror 28. This displacement reduces the coupling efficiency of the input coupling field of the measurement radiation 18, radiated onto the resonator mirror 28 via the input coupling lens element 22, with the mode field in the resonator 26, whereby the measurement accuracy of the measurement arrangement is reduced. This effect can be weakened by virtue of the beam diameter of the measurement radiation 18 radiated onto the resonator mirror 28 being increased to such an extent that the lateral offset remains under a limit of 0.1 beam radii. However, at the same time this also means that the beam diameter on the measurement mirror 14 becomes substantially smaller; effectively there is then focusing on the measurement mirror 14. However, this may be undesirable for metrological reasons since this increases the sensitivity to the local surface topography of the measurement mirror 14. Moreover, impractically large beam diameters would arise on the input coupling side if values of more than 10 mm are chosen for the working distance d_{M}.

By contrast, on account of the arrangement of the centre m2 of the curvature of the resonator mirror 30 on the measurement mirror 14, the lateral position of the chief ray 18h on the resonator mirror 28 is perfectly stable in the embodiment according to the disclosure of the measurement arrangement 10 as per FIG. 2A. The reason for this is that the position of the centre of curvature m2 of the resonator mirror 30, as seen from the resonator mirror 28 via the measurement mirror 14, remains unchanged even when the measurement mirror 14 is tilted. Should the centre of curvature m2 of the resonator mirror 30 deviate from the position on the measurement mirror 14 by no more than 10% of the working distance d_{M}, i.e. only to a small extent, like in the embodiment according to FIG. 1, there is only a small lateral displacement of the resonator mode on the resonator mirror 28, the influence of which on the coupling efficiency, and hence on the measurement accuracy, is tolerable.

The course of the beam path 18r of the measurement radiation 18, folded by the measurement mirror 14, within the optical resonator 26 corresponds in the embodiment according to FIG. 1 to that of a Gaussian beam, whose beam waist T (reference sign 38) is located centrally between the measurement mirror 14 and the resonator mirror 30 in the depicted embodiment. That is to say, a waist distance d_{T} from the resonator mirror 30 is 50% of the working distance d_{M} in this case, i.e. a relative distance a=d_{T}/d_{M} is 0.5. The boundary lines plotted in FIG. 1 for representing the beam path 18r of the measurement radiation each correspond in the cross section of the beam path to the locations at which the intensity is 1/e² of the maximum intensity at the centre of the beam path. The corresponding beam cross section represented by these boundary lines has a beam radius r1 at the mirror 28, a beam radius rm at the measurement mirror 14 and a beam radius r2 at the mirror 30.

The radius of curvature R1 of the resonator mirror 28 is chosen according to the following design rule:

$$R 1 = R 2 ( 3 + \frac{2}{- 2 + a} )$$

—this relationship is depicted in FIG. 5 for a fixedly predefined radius of curvature R2. In alternative exemplary embodiments, the value of R1 deviates from

$$R 2 ( 3 + \frac{2}{- 2 + a} ) ,$$

but by no more than 10%.

The choice of a value for the distance a is based on the considerations explained below. For the Rayleigh length z_{R} in the optical resonator 26, the following relationship with the relative distance a arises given the condition that the centre m2 is located on the measurement mirror 14: z_{R}=\sqrt{a−a²}—see FIG. 4. As a person skilled in the art is aware, the Rayleigh length z_{R} denotes the distance along the optical axis used by a laser beam for its cross-sectional area to double, starting from its beam waist. As evident in FIG. 4, the Rayleigh length z_{R} tends to 0 for a→0 and a→1, and it is at a maximum for a=0.5.

The beam radii r1, rm and r2 arising as a function of a are depicted in FIG. 6. For a→0, the beam radii r1 and rm tend to infinity, while r2 tends to 0. For a→1, the beam radii r1 and r2 tend to infinity and rm tends to 0. In an exemplary embodiment, the following applies: 0.05≤a≤0.95, i.e. the distance d_{T} of the beam waist T from the resonator mirror 30 or the distance d_{M}−d_{T} of the beam waist T from the measurement mirror is at least 5% of the working distance d_{M} in each case. For this dimensioning of a, the dimensions of the beam radii r1, r2 and rm are in a range in which stable modes can form in the optical resonator 26 and which is in a manageable extent with regards to the installation space used for the mirrors of the resonator 26. The sum of the beam radii r1 and r2, which substantially determines the dimensioning of the measurement arrangement 10 in the y-direction, has a similar value for a=0.05 as for a=0.95. According to further exemplary embodiments, the following applies: 0.1≤a≤0.9 or 0.2≤a≤0.8. The measurement arrangement 10 can be designed more compactly and the mode stability is further improved for these values.

FIG. 7 illustrates an embodiment 110 of a measurement arrangement according to the disclosure, which is configured like the measurement arrangement 10 for determining the position of a movable component in a microlithographic optical system 500. The measurement arrangement 110 only differs from the measurement arrangement 10 in that the resonator mirrors 28 and 30 are offset from one another in the z-direction, that is to say substantially in relation to the direction of incidence of the measurement radiation 18 at the resonator mirrors 28 and 30, i.e. in the axial direction.

In the present example, the resonator mirror 30 is offset in the negative z-direction such that the distance from the measurement mirror 14 increases. Hence, the resonator mirror 30 can also be slightly offset transversely to the direction of incidence 18, to be precise in such a way that edge regions 128r and 130r of the resonator mirrors 28 and 30 made available to the beam path of the measurement radiation 18 are not arranged in overlapping fashion. This allows the folding angle β to be reduced in comparison with the measurement arrangement 10. This can reduce the effect of an axial displacement of the measurement mirror 14, i.e. a displacement of the measurement mirror along the z-axis during measurement operation, on the position of the mode at the resonator mirrors 28 and 30. As seen from the resonator mirror 28 in reflection via the measurement mirror 14, an axial displacement of the measurement mirror 14 through Δz brings about a lateral displacement of the centre of curvature m2 through 2 β Δz in relation to the measurement mirror 14. The lateral displacement of the mode on the resonator mirror 28 is greater by a factor of R1/(R1−R2) on account of the “lever effect”. Hence, the lateral displacement of the measurement mirror 14 allowed during measurement operation can be set to be larger in the embodiment according to FIG. 7 than in the embodiment according to FIG. 1 on account of the reduction in the folding angle β.

FIG. 8 illustrates an embodiment 210 of a measurement arrangement according to the disclosure, which is configured like the measurement arrangement 10 for determining the position of a movable component in a microlithographic optical system 500. The measurement arrangement 210 differs from the measurement arrangement 10 in that polarized measurement radiation 218 is radiated onto the optical resonator 26, for instance by using an upstream polarizer 260, and in that a polarization beam splitter 262 and a quarter wave plate 264 are arranged in the beam path of the measurement radiation 18 between the resonator mirror 28 and the measurement mirror 14. The measurement radiation 18 reflected back by the measurement mirror 14 is deflected through 90° by the polarization beam splitter 262. The resonator mirror 30 is arranged in a corresponding position, oriented transversely to the resonator mirror 28, below the polarization beam splitter 262.

The folding angle β can be reduced to less than 1 mrad, for example to 0 mrad, by output coupling the measurement radiation 18 directed at the resonator mirror 30 from the beam path between the resonator mirror 28 and the measurement mirror 14. Hence, the directions of the measurement radiation 18 travelling to the measurement mirror 14 and of the reflected measurement radiation 18 are collinear. This can further reduce the effect of an axial displacement of the measurement mirror 14, i.e. a displacement of the measurement mirror 14 along the z-axis during measurement operation, on the position of the mode at the resonator mirrors 28 and 30, and hence further increase the admissible axial displacement of the measurement mirror 14.

FIG. 9 illustrates an embodiment 310 of a measurement arrangement according to the disclosure, which is configured like the measurement arrangement 10 for determining the position of a movable component in a microlithographic optical system 500. Like in the measurement arrangement 210 according to FIG. 8, the directions of the measurement radiation 18 travelling to the measurement mirror 14 and of the reflected measurement radiation 18 are collinear in the measurement arrangement 310.

The measurement arrangement 310 differs from the measurement arrangement 10 according to FIG. 1 in that the resonator 26 is operated in a Laguerre-Gauss mode with an azimuthal index of at least one; in the present case, a Laguerre-Gauss mode 366 with an azimuthal index of 3 and a radial index of 0 is generated. The coupling to the mode 366 can be implemented using suitable beam shaping, e.g., with a CGH not depicted in the drawing. By generating the mode 366, substantially defining a ring-shaped intensity distribution, in the optical resonator 26, it is possible to arrange the resonator mirror 330 serving as counter mirror (analogous to the resonator mirror 30 according to FIG. 1) in a central cutout 368 of the resonator mirror 328 serving as input coupling mirror (analogous to the resonator mirror 28 according to FIG. 1).

In a manner analogous to the embodiment 210 according to FIG. 8, this can reduce the effect of an axial displacement of the measurement mirror 14, i.e. a displacement of the measurement mirror 14 along the z-axis during measurement operation, on the position of the mode at the resonator mirrors 328 and 330 in the embodiment 310 on account of the collinear beam arrangement, and hence increase the admissible axial displacement of the measurement mirror 14.

The above description of exemplary embodiments, embodiments or embodiment variants should be understood to be by way of example. The disclosure effected thereby firstly can enable the person skilled in the art to understand the present disclosure and the features associated therewith, and secondly encompasses alterations and modifications of the described structures and methods that are also obvious in the understanding of the person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Measurement arrangement
12 Measuring head
14 Measurement mirror
15 Reflective surface
16 Radiation generation and evaluation device
18 Measurement radiation
18r Beam path of the measurement radiation in the resonator
18h Central chief ray of the measurement radiation in the resonator
20 Optical fibre
22 Input coupling lens element
26 Optical resonator
28 Resonator mirror
29 Centre of curvature m1
30 Resonator mirror
31 Centre of curvature m2
32 Resonator cavity
34 Working distance d_{M}
36 Folding angle β
38 Beam waist T
42 Laser
44 Faraday isolator
46 Electro-optic modulator
48 Polarization-optical beam splitter
50 Quarter wave plate
52 Photodetector
54 Low-pass filter
56 Beam splitter
58 Analyser
110 Measurement arrangement
128r Edge region
130r Edge region
210 Measurement arrangement
218 Polarized measurement radiation
260 Polarizer
262 Polarization beam splitter
264 Quarter wave plate
310 Measurement arrangement
328 Resonator mirror
330 Resonator mirror
366 Laguerre-Gauss mode
368 Central cutout
500 Optical system
502 Support structure
503 Field facet mirror
504 Pupil facet mirror
506 Plasma light source
508 Collector mirror
510 First telescope mirror
512 Second telescope mirror
514 Deflection mirror
515 Illumination device
516 Projection lens
518, 520, 522, 524, 528 Mirrors of the projection lens
526 Mirror of the projection lens as movable component
527 Reflective side
530 Mask
532 Mask stage
534 Substrate
536 Wafer stage
R1 Radius of curvature of the resonator mirror S1
R2 Radius of curvature of the resonator mirror S2

What is claimed is:

1. A measurement arrangement, comprising:
an optical resonator comprising first and second resonator mirrors enclosing a resonator cavity; and
a movable measurement mirror assigned to a movable component in a microlithographic optical system, the movable measurement mirror disposed within the resonator cavity to direct a measurement radiation back and forth between the first and second resonator mirrors,
wherein:
the movable measurement mirror is a working distance from the first resonator mirror;
the first resonator mirror comprises a curvature matched to the movable measurement mirror so that a center of the curvature of the first resonator mirror is a distance from the movable measurement mirror that is at most 20% of the working distance.

2. The measurement arrangement of claim 1, wherein:
the second resonator mirror comprises an input coupling mirror configured to couple the measurement radiation into the resonator cavity; and
the first resonator mirror comprises a counter mirror to the input coupling mirror.

3. The measurement arrangement of claim 1, wherein:
the optical resonator is configured to form a beam path for the measurement radiation; and
the beam path has a beam waist between the movable measurement mirror and the first resonator mirror.

4. The measurement arrangement of claim 3, wherein:
the beam waist is a distance of at least 5% of the working distance from the movable measurement mirror; and
the beam waist at a distance of at least 5% of the working distance from the first resonator mirror.

5. The measurement arrangement of claim 1, wherein:
the second resonator mirror comprises a curvature with a center on a side of the movable measurement mirror opposite the second resonator mirror; and
the center of the curvature of the second resonator mirror is a distance of at least 10% of the working distance from the movable measurement mirror.

6. The measurement arrangement of claim 3, wherein the second resonator mirror comprises a curvature, and
$$R 1 = R 2 ( 3 + \frac{2}{- 2 + a} ) \pm 10 \% ,$$
where R1 is the radius of curvature of the second resonator mirror, R2 is the radius of curvature of the first resonator mirror, and a is a relative distance of the beam waist from the first resonator mirror.

7. The measurement arrangement of claim 1, wherein the movable measurement mirror comprises a plane mirror.

8. The measurement arrangement of claim 1, wherein the optical resonator is configured so that the measurement radiation radiated at the movable measurement mirror makes an angle of no more than 100 mrad with the measurement radiation reflected thereon.

9. The measurement arrangement of claim 8, wherein the first and second resonator mirrors are offset from each other relative to a direction of incidence of the measurement radiation at the movable measurement mirror.

10. The measurement arrangement of claim 1, wherein the optical resonator is configured so that the measurement radiation radiated at the movable measurement mirror makes an angle of no more than 1 mrad with the measurement radiation reflected thereon.

11. The measurement arrangement of claim 1, further comprising a polarization beam splitter in a beam path of the optical resonator, wherein a beam path of the measurement radiation between the movable measurement mirror and the first or second resonator mirror is deflected by the polarization beam splitter.

12. The measurement arrangement of claim 1, wherein the optical resonator is configured to be operated in a Laguerre-Gauss mode with an azimuthal index of at least 1.

13. The measurement arrangement of claim 1, wherein the first resonator mirror or the second resonator mirror comprises a central cutout in which the other resonator mirror is arranged.

14. The measurement arrangement of claim 1, wherein the working distance is at least 2 cm.

15. The measurement arrangement of claim 1, wherein the center of the curvature of the first resonator mirror is on the movable measurement mirror.

16. The measurement arrangement of claim 15, wherein:
the second resonator mirror comprises an input coupling mirror configured to couple the measurement radiation into the resonator cavity; and
the first resonator mirror comprises a counter mirror to the input coupling mirror.

17. The measurement arrangement of claim 15, wherein:
the optical resonator is configured to form a beam path for the measurement radiation; and
the beam path has a beam waist between the movable measurement mirror and the first resonator mirror.

18. An apparatus, comprising:
the measurement arrangement of claim 1,
wherein the apparatus comprises a microlithographic projection exposure apparatus.

19. The apparatus of claim 18, comprising a plurality of optical elements for guiding exposure radiation in the projection exposure apparatus, with one of the optical elements comprises the movable component.

20. An optical system, comprising:
a movable component; and
the measurement arrangement of claim 1,
wherein:
the measurement arrangement is configured to determine a position of the movable component; and
the optical system comprises an Illumination device for a microlithographic projection exposure apparatus, a projection lens for a microlithographic projection exposure apparatus, an inspection apparatus configured to inspect a surface of a substrate, or a coordinate measuring apparatus.
